(19) United States
(12) Patent Application Publication
(10) Pub. No.: US 2007/0113124 A1
(43) Pub. Date: May 17, 2007

(54) Method of testing integrated circuit and apparatus therefor

(76) Inventors: Chi-Tung Chang, Taipei City (TW); Kuang-Ting Hu, Taipei City (TW)

Correspondence Address: Dykema Gossett, PLLC, Suite 300 West, 1300 I Street, N.W., Washington, DC, 20005-3306, US

(21) Appl. No.: 11/272,064

(22) Filed: Nov. 14, 2005

(51) Int. Cl. G01R 31/28

(52) U.S. Cl. 714/724

(57) ABSTRACT

In a method of testing integrated circuit (IC), a personal computer host and related software and hardware are used to constitute a system for conducting and controlling IC test. The method includes the steps of: (a) starting the test and using the computer host to drive a loading-unloading device to position an IC to be tested on a testing module; (b) determining whether a testing unit electrically connected to the testing module is in a normal condition or not; (c) driving the testing unit, if it is in normal condition, so as to test the IC positioned on the testing module; (d) picking up and collecting the tested IC to position it in a specific collecting box, depending on whether the tested IC is normal or abnormal; and (e) ending the test. The test of IC can be economically and conveniently conducted through controlling the personal computer host.

### FIELD OF THE INVENTION

The present invention relates to method and apparatus for testing integrated circuit (IC), and more particularly to method and apparatus for economically and conveniently testing IC.

### BACKGROUND OF THE INVENTION

Following the rapid development in different technical branches, various types of electronic products with extremely fast operating speed have been introduced into the markets. As a result, a large quantity of various integrated circuits (ICs or chips) having more functions, faster operating speed, and largely reduced volume for using with these electronic products have also been quickly developed. As a common practice, before the ICs could be delivered to customers, they must pass quality test to determine the yield of every batch of produced ICs and to separate the normal ICs from the abnormal ones, lest the delivered ICs should be rejected by customers due to poor quality. In a worse condition, the customers might withdraw the orders or claim for indemnification.

FIG. 1 is a block diagram of an IC testing apparatus 1 currently available in the market. As shown, the conventional IC testing apparatus 1 includes a testing unit 11 that cooperates with a loading-unloading device 12 to insert an IC to be tested into a testing socket 13. Then, test vectors are input into the testing unit 11, and automatic testing equipment (ATE) testing programs are used to conduct the test. When the test is finished, the loading-unloading device 12 is used to separate the qualified ICs from the unqualified ones, and the test is ended. FIG. 2 is a perspective view of another conventional testing apparatus 2. Since the testing apparatus 2 includes a testing unit 22 that provides only the function of measuring test signals, a microcomputer controller 21 must be connected to the testing unit 22 to control the operation of the whole testing apparatus 2. Moreover, the testing unit 22 is further connected to a signal analyzing unit 23, in order to receive induced data produced at the time the testing unit 22 is in contact with the tested IC, and analyze the received data to determine whether the tested IC is normal or not.

According to a basic definition of test vectors, vectors are logic 1 and logic 0 representing input or output when every clock tick is applied to a pin on an element. Since logic 1 and logic 0 are presented by waveforms with timing and electrical level characteristics, they are related to the shape of the waveform, the pulse width, the pulse edge, the pulse steepness, and the positions of pulse rise edge and pulse fall edge. In the automatic test equipment (ATE), these waveforms are expressed by rise edge and fall edge, as well as a formatted description of the requirements for forming time and duration of the element pins. The test vectors used in the currently available testing programs include three basic sources: (1) most function vectors are generated via circularized simulation; (2) almost all the scan vectors are automatically generated from test modes or from engineering design automation (EDA) tools; and (3) some special technique vectors, such as JTAG, logic BIST, and memory BIST, are generated by target EDA tools.

Since the conventional testing apparatus are very expensive and include specially designed and manufactured signal analyzing units that require extremely high maintenance cost, and the test vectors are mainly generated from software instead of actual IC working conditions, they are not able to detect all the defects in the tested ICs and could not satisfy the demands for advanced quality. Moreover, for the purpose of testing ICs that have increasingly high frequency and complicate functions, it is necessary to frequently replace the old signal analyzing units with new ones. Meanwhile, it is more and more difficult to develop usable testing programs. This factor plus the expensive testing equipment often adversely affects the delivery of the tested ICs. With the conventional testing apparatus, a user has to operate the microcomputer controller and the signal analyzing unit at the same time. This is of course very inconvenient to the user. In a worse condition, when a failure occurs, it is uneasy for the user to determine which part of the testing apparatus has caused the failure. It is therefore difficult to handle the failure efficiently.

It is therefore tried by the inventor to develop a method of testing IC and the apparatus therefor, in order to overcome the drawbacks existed in the conventional IC testing apparatus.

### SUMMARY OF THE INVENTION

A primary object of the present invention is to provide an integrated circuit (IC) testing apparatus that can be easily operated and provides sufficient error coverage to save testing cost. To achieve this object, the IC testing apparatus of the present invention includes a personal computer host, at least one testing unit, at least one testing module, which is an IC peripheral applied circuit, and a loading-unloading device. When the IC testing apparatus of the present invention cooperates with related software and hardware as well as control system, it is able to perform all the IC testing functions that were otherwise performed using the conventional expensive testing equipment. The testing apparatus of the present invention is designed to simulate the exact condition for testing an IC, in which the IC to be tested is soldered to a customer designated printed circuit board (PCB). The testing conditions may be exactly the same as those designated by the customer.

Another object of the present invention is to provide an IC testing method in which a personal computer system is used to enable a user to easily determine which part of the testing apparatus is failed when a failure occurs in the process of testing.

To achieve the above object, in the method of testing integrated circuit (IC) according to the present invention, a personal computer host and related software and hardware are used to constitute a system for conducting and controlling IC test. The method includes the steps of: (a) starting the test and using the computer host to drive a loading-unloading device to position an IC to be tested on a testing module; (b) determining whether a testing unit electrically connected to the testing module is in a normal condition or not; (c) driving the testing unit, if it is in normal condition, so as to test the IC positioned on the testing module; (d) picking up and collecting the tested IC to position it in a specific collecting box, depending on whether the tested IC is normal or abnormal; and (e) ending the test. The test of IC can be economically and conveniently conducted through controlling via the personal computer host.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a block diagram of a conventional apparatus for testing integrated circuit;

FIG. 2 is a perspective view of another conventional apparatus for testing integrated circuit;

FIG. 3 is a flowchart showing steps included in a method of testing integrated circuit according to a first embodiment of the present invention;

FIG. 4 is a flowchart showing steps included in a method of testing integrated circuit according to a second embodiment of the present invention;

FIG. 5 is a block diagram of an apparatus for testing integrated circuit according to a first embodiment of the present invention; and

FIG. 6 is a block diagram of an apparatus for testing integrated circuit according to a second embodiment of the present invention.

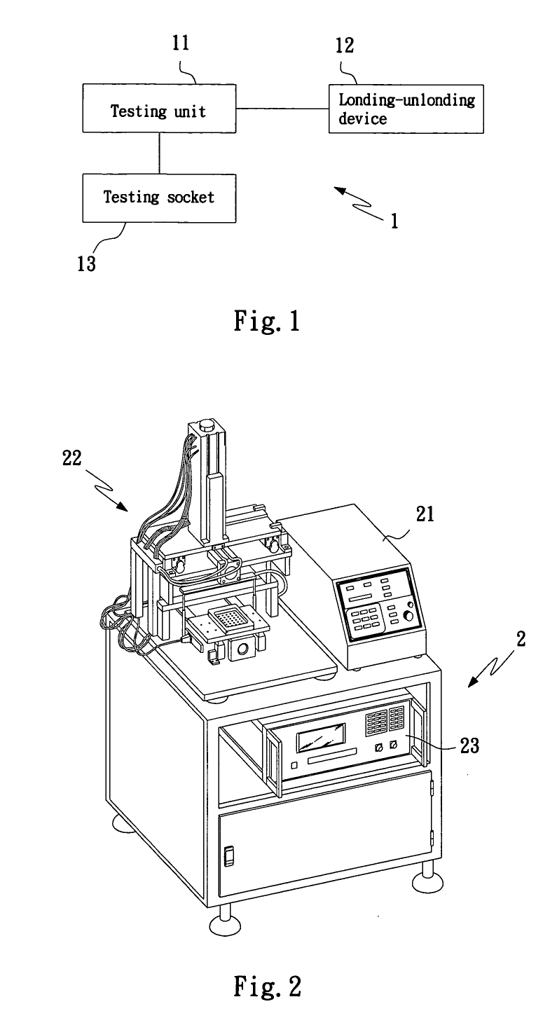

### DETAILED DESCRIPTION OF THE PREFERRED EMBODIMENTS

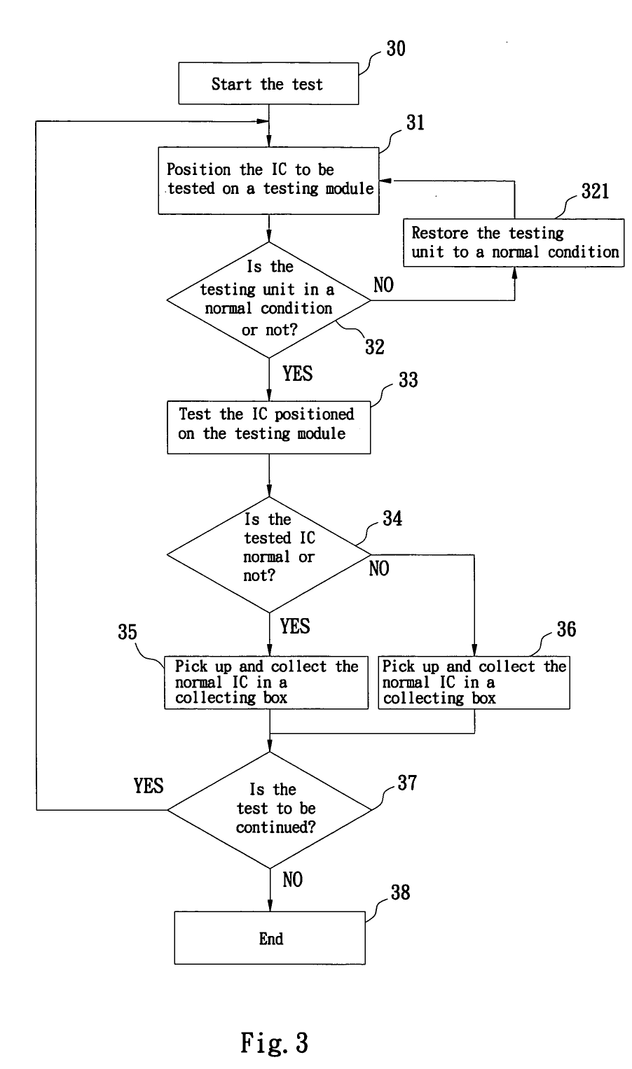

Please refer to FIG. 3 that is a flowchart showing steps included in a method of testing integrated circuit (IC) according to a first embodiment of the present invention.

As shown, a first step in the method of testing IC according to the first embodiment of the present invention is to start the test (Step 30). At this point, a computer host is actuated to drive a loading-unloading device to position an IC to be tested on a testing module (Step 31). Then, it is determined whether a testing unit connected to the testing module is in a normal condition or not (Step 32). If it is determined the testing unit is not in the normal condition, the testing unit is restored to a condition capable of doing the test (Step 321), and the Step 32 is repeated. Or, if it is determined the testing unit is in the normal condition, the testing unit is driven to test the IC positioned on the testing module (Step 33), and it is further determined whether the tested IC is in a normal condition or not (Step 34). Then, the tested IC being determined as normal is picked up and collected (Step 35), and the tested IC being determined as abnormal is separately picked up and collected (Step 36). Thereafter, it is determined whether the test is to be continued or not (Step 37). If it is determined to continue the test, the Step 31 is repeated again; or, if it is determined not to continue the test, the current test is ended (Step 38).

Wherein, the Step 34 of determining whether the tested IC is in the normal condition or not is conducted using the computer host. That is, test vectors and testing programs existed in the computer host are used to automatically analyze an induced output of the tested IC.

The Steps 35 and 36 of picking up and collecting the normal and the abnormal IC, respectively, are conducted using the loading-unloading device, such that the normal and the abnormal IC are separately collected and positioned in different collecting boxes.

The Step 37 of determining whether to continue the test or not is conducted using the computer host, which automatically judges whether there is any further IC to be tested.

In the above-described method of testing IC according to the present invention, a personal computer is used and related software and hardware are developed to thereby effectively reduce the cost for purchasing related testing equipment. Moreover, by positioning the IC in a modular structure to actually test the IC function, an increased coverage of test may be obtained to meet all testing requirements. Moreover, a user conducting the test needs only to operate one single interface, that is, the computer host. Therefore, the method of the present invention is very convenient to operate and control. In the event a failure occurs, the computer host would automatically detect the failed part of the whole testing system, allowing the maintenance personnel to repair the failed part within the shortest time.

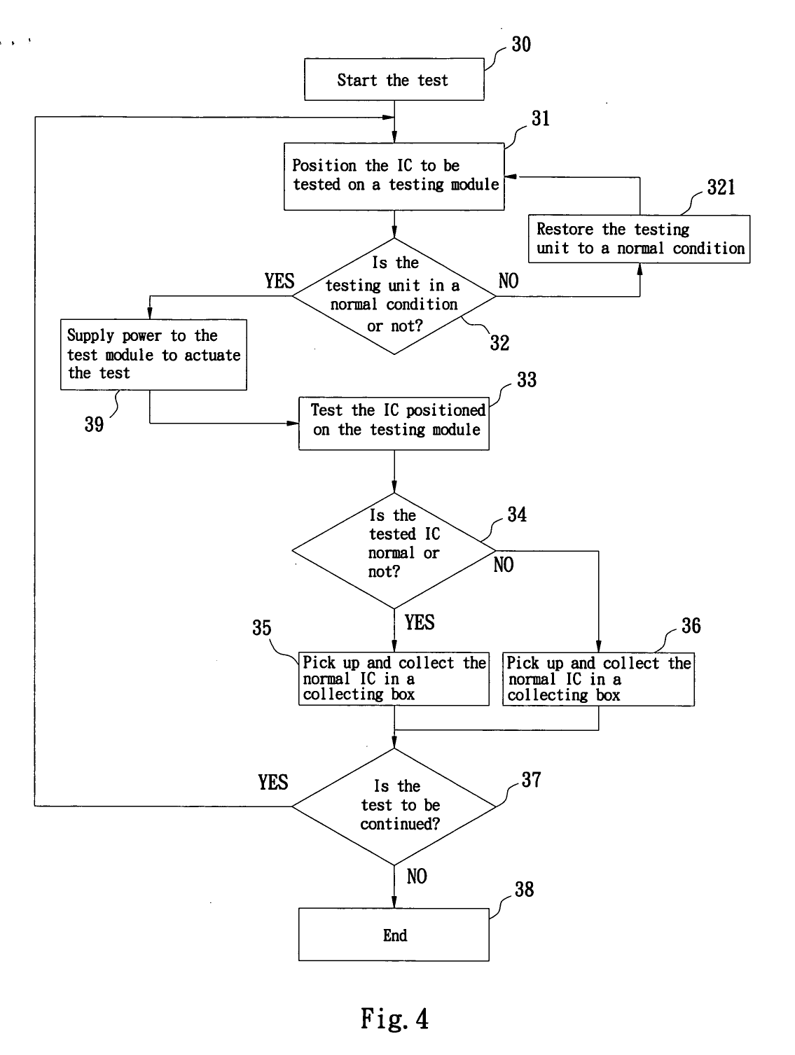

FIG. 4 is a flowchart showing the steps included in a method of testing IC according to a second embodiment of the present invention. As shown, a first step in the method of testing IC according to the second embodiment of the present invention is to start the test (Step 30). At this point, a computer host is actuated to drive a loading-unloading device to position an IC to be tested on a testing module (Step 31). Then, it is determined whether a testing unit connected to the testing module is in a normal condition or not (Step 32). If it is determined the testing unit is not in the normal condition, the testing unit is restored to a condition capable of doing the test (Step 321), and the Step 32 is repeated. Or, if it is determined the testing unit is in the normal condition, power needed to actuate the testing module is supplied to the testing module (Step 39), and the testing unit is driven to test the IC positioned on the testing module (Step 33), and it is further determined whether the tested IC is in a normal condition or not (Step 34).

Then, the tested IC being determined as normal is picked up and collected (Step 35), and the tested IC being determined as abnormal is separately picked up and collected (Step 36). Thereafter, it is determined whether the test is to be continued or not (Step 37). If it is determined to continue the test, the Step 31 is repeated again; or, if it is determined not to continue the test, the current test is ended (Step 38).

Wherein, the Step 34 of determining whether the tested IC is in the normal condition or not is conducted using the computer host. That is, test vectors and testing programs existed in the computer host are used to automatically analyze an induced output of the tested IC.

The Steps 35 and 36 of picking up and collecting the normal and the abnormal IC, respectively, are conducted using the loading-unloading device, such that the normal and the abnormal IC are separately collected and positioned in different collecting boxes.

The Step 37 of determining whether to continue the test or not is conducted using the computer host, which automatically judges whether there is any further IC to be tested.

In the above-described method of testing IC according to the present invention, a personal computer is used and related software and hardware are developed to thereby effectively reduce the cost for purchasing related testing equipment. Moreover, by positioning the IC in a modular structure to actually test the IC function, an increased coverage of test may be obtained to meet all testing requirements. Moreover, a user conducting the test needs only to operate one single interface, that is, the computer host. Therefore, the method of the present invention is very convenient to operate and control. In the event a failure occurs, the computer host would automatically detect the failed part of the whole testing system, allowing the maintenance personnel to repair the failed part within the shortest time.

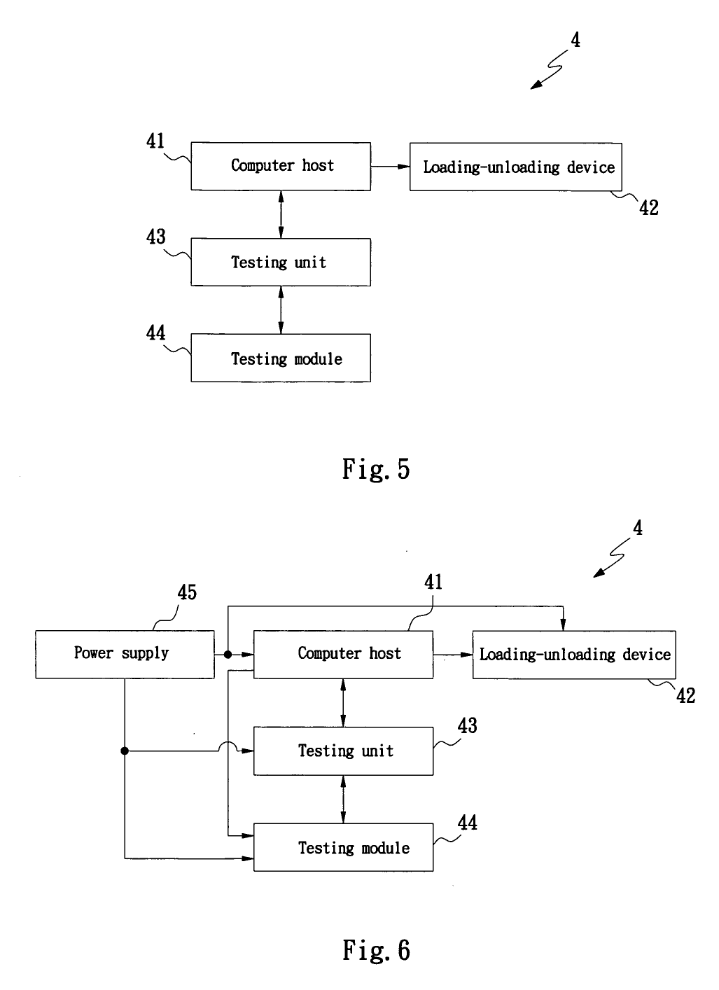

Please refer to FIG. 5 that is a block diagram of an IC testing apparatus 4 according to a first embodiment of the present invention. As shown, the IC testing apparatus 4 in the first embodiment includes at least a computer host 41; a testing unit 43 electrically connected to the computer host 41 to receive test signals transmitted from the computer host 41 and send test data back to the computer host 41; a testing module 44 electrically connected to the testing unit 43 for an IC to be tested to position thereon, so that pins on the IC are tested; and a loading-unloading device 42 electrically connected to the computer host 41 and capable of loading or unloading the tested IC on or from the testing module 44 under control of the computer host 41. More specifically, the computer host 41 is electrically connected to the loading-unloading device 42 via a transistor-transistor logic (TTL) unit, in order to control the movement of the loading-unloading device 42. The loading-unloading device 42 may be, for example, a mechanical arm to load or unload the IC on or from the test module 44 using suction force or clamp force.

The computer host 41 is electrically connected to the testing unit 43 via an RS232 interface, in order to allow the transmission of data between the computer host 41 and the testing unit 43, and restore the testing unit 43 to a normal condition when the testing unit 43 is found abnormal.

The IC testing apparatus 4 is very convenient for manipulation, because a user needs only to operate one single interface, that is, the computer host 41, to conduct the test. In the event any failure occurs, the computer host 41 would automatically detect the failed part of the IC testing apparatus 4, allowing maintenance personnel to repair the apparatus within the shortest time.

FIG. 6 is a block diagram of an IC testing apparatus 4 according to a second embodiment of the present invention. As shown, the IC testing apparatus 4 in the second embodiment includes at least a computer host 41; a testing unit 43 electrically connected to the computer host 41 to receive test signals transmitted from the computer host 41 and send test data back to the computer host 41; a testing module 44 electrically connected to the testing unit 43 and the computer host 41 for an IC to be tested to position thereon, so that pins on the IC are tested; a loading-unloading device 42 electrically connected to the computer host 41 and capable of loading or unloading the tested IC on or from the testing module 44 under control of the computer host 41; and a power supply 45 electrically connected to the computer host 41, the testing unit 43, the testing module 44, and the loading-unloading device 42 to supply power needed to actuate these parts.

The testing module 44 is electrically connected to the computer host 41, so that the start and shut down of the testing module 44 is directly controlled by the computer host 41. In this manner, the testing module 44 can be started only when everything is ready for testing ICs to thereby achieve the purpose of power economy.

The computer host 41 is electrically connected to the loading-unloading device 42 via a transistor-transistor logic (TTL) unit, in order to control the movement of the loading-unloading device 42. The loading-unloading device 42 may be, for example, a mechanical arm to load or unload the IC on or from the test module 44 using suction force or clamp force.

The computer host 41 is electrically connected to the testing unit 43 via an RS232 interface, in order to allow the transmission of data between the computer host 41 and the testing unit 43, and restore the testing unit 43 to a normal condition when the testing unit 43 is found abnormal.

The IC testing apparatus 4 is very convenient for manipulation, because a user needs only to operate one single interface, that is, the computer host 41, to conduct the test. In the event any failure occurs, the computer host 41 would automatically detect the failed part of the IC testing apparatus 4, allowing maintenance personnel to repair the apparatus within the shortest time.

In the method and apparatus of the present invention, since a personal computer host is used to conduct the test of integrated circuit, it is not necessary to frequently replace the IC testing apparatus with a new one, and the user needs only to operate one single interface, that is, the computer host, in performing the test. The method and apparatus for testing IC according to the present invention are therefore economical and convenient to control.

What is claimed is:

1. A method of testing integrated circuit (IC), comprising the steps of:
(a) using a computer host to drive a loading-unloading device to position an IC to be tested on a testing module;
(b) determining whether a testing unit electrically connected to said testing module is in a normal condition or not; and restoring said testing unit to a condition capable of testing an IC, if it is determined said testing unit is not in a normal condition;
(c) driving said testing unit to test the IC positioned on said testing module, and determining whether the tested IC is normal or not;
(d) picking up and collecting the tested IC that is determined as a normal IC, or separately picking up and collecting the tested IC that is determined as an abnormal IC; and
(e) determining whether there is any further IC to be tested or not; and ending the test if it is determined no further IC is to be tested.

2. The method of testing IC as claimed in claim 1, wherein, in the step (c), test vectors and testing programs existed in said computer host are used to automatically analyze an induced output of the tested IC, so as to determine whether the tested IC is normal or not.

3. The method of testing IC as claimed in claim 1, wherein, in the step (d), the tested IC determined as normal is picked up and collected using said loading-unloading device, and the collected normal IC is positioned in a collecting box.

4. The method of testing IC as claimed in claim 1, wherein, in the step (d), the tested IC determined as abnormal is picked up and collected using said loading-unloading device, and the collected abnormal IC is positioned in a collecting box.

5. The method of testing IC as claimed in claim 1, wherein, in the step (e), the determining of whether there is any further IC to be tested is automatically executed by said computer host.

6. An integrated circuit (IC) testing apparatus, comprising:
a computer host;
a testing unit electrically connected to said computer host to receive test signals transmitted from said computer host and send test data back to said computer host;
a testing module electrically connected to said testing unit and said computer host for an IC to be tested to position thereon, so that pins on the IC are tested; and
a loading-unloading device electrically connected to said computer host and capable of loading or unloading the IC on or from said testing module under control of said computer host.

7. The IC testing apparatus as claimed in claim 6, wherein said computer host, said testing unit, said testing module, and said loading-unloading device are separately electrically connected to a power supply.

8. The IC testing apparatus as claimed in claim 6, wherein said testing module electrically connected to said computer host is directly controlled by said computer host to start or shut down.

9. The IC testing apparatus as claimed in claim 6, wherein said computer host is electrically connected to said loading-unloading device via a transistor-transistor logic (TTL) unit to control movements of said loading-unloading device.

10. The IC testing apparatus as claimed in claim 6, wherein said loading-unloading device is a mechanical arm.

11. The IC testing apparatus as claimed in claim 6, wherein said computer host is electrically connected to said testing unit via an RS232 interface, in order to allow the transmission of data between said computer host and said testing unit, and restore said testing unit to a normal condition when said testing unit is found abnormal.
